(19) United States
(12) Patent Application Publication
(10) Pub. No.: US 2026/0236168 A1
(43) Pub. Date: Aug. 13, 2026

(54) REFRESH COMMAND FOR MULTIPLE MEMORY BANKS OF MULTIPLE MEMORY DIES

(71) Applicants: Advanced Micro Devices, Inc., Santa Clara, CA (US); ATI Technologies ULC, Markham (CA)

(72) Inventors: Michael LITT, Ontario (CA); Yubin YAO, Santa Clara, CA (US)

(21) Appl. No.: 19/048,708

(22) Filed: Feb. 7, 2025

(51) Int. Cl. G06F 3/06; G11C 11/406

(52) U.S. Cl. CPC G06F 3/061; G06F 3/0659; G06F 3/0673; G11C 11/406

(57) ABSTRACT

A memory system includes one or more memory dies and a memory controller. The one or more memory dies have a first memory bank, a second memory bank, a third memory bank, and a fourth memory bank. The first memory bank is associated with a first identifier and the third memory bank is associated with a second identifier. The memory controller circuitry is coupled to the one or more memory dies. The memory controller circuitry outputs a refresh command to the one or more memory dies to refresh the first memory bank and the third memory bank during a first period. The second memory bank and the fourth memory bank are accessible by the memory controller circuitry during the first period.

### TECHNICAL FIELD

Examples of the present disclosure generally relate to refreshing multiple memory banks across multiple memory dies.

### BACKGROUND

A memory device includes multiple memory integrated circuit (IC) dies. The memory IC dies, or memory dies, are interconnected with each other. A memory controller is coupled to the memory IC dies via channels. The memory controller communicates read/write command signals and refresh signals to the memory IC dies via the channels. The refresh signals instruct the memory IC dies to perform a memory refresh process. The refresh signals control how often a memory refresh process is performed. A memory refresh process includes periodically reading information from an area of a memory IC die, and rewriting the information to the same area. The process of reading and writing the data preserves the data. In a memory IC die, each bit of memory data is stored as the presence or absence of an electric charge on a capacitive element(s). Overtime, the electric charge decreases (e.g., leaks away). The electric charge may decrease to the point where the stored data is lost. Refreshing the data restores the electric charge, preserving the data. A memory refresh cycle is used to repeatedly perform the refresh process.

### SUMMARY

In one example, a memory system includes one or more memory dies and a memory controller. The one or more memory dies have a first memory bank, a second memory bank, a third memory bank, and a fourth memory bank. The first memory bank is associated with a first identifier and the third memory bank is associated with a second identifier. The memory controller circuitry is coupled to the one or more memory dies. The memory controller circuitry outputs a refresh command to the one or more memory dies to refresh the first memory bank and the third memory bank during a first period. The second memory bank and the fourth memory bank are accessible by the memory controller circuitry during the first period.

In one example, a memory controller of a memory system outputs a refresh command to one or more memory dies of the memory system to refresh a first memory bank of the one or more memory dies and a third memory bank of the one or more memory dies during a first period. A second memory bank of the one or more memory dies and a fourth memory bank of the one or more memory dies are accessible by the memory controller during the first period.

A method includes outputting, from memory controller circuitry to one or more memory dies, a refresh command. The method further includes refreshing, a first memory bank of the one or more memory dies and a third memory bank of the one or more memory dies during a first period based on the refresh command. A second memory bank of the one or more memory dies and a fourth memory bank of the one or more memory dies are accessible by the memory controller circuitry during the first period.

These and other aspects may be understood with reference to the following detailed description.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a block diagram of a memory system.

FIG. 2 illustrates a block diagram of a memory device.

FIG. 3 illustrates a block diagram of a memory die.

FIG. 4 illustrates a block diagram of a portion of a memory device.

FIG. 5 illustrates a flowchart of a method for refreshing memory banks of a memory device.

FIG. 6 illustrates a block diagram of a computer system.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

A memory device includes multiple memory integrated circuit (IC) dies or chips. A memory IC die may be referred to as a memory die. Each memory IC die includes one or more memory cells (e.g., bitcells) that store bit values. The memory device is coupled to a memory controller (memory controller circuitry). The memory controller controls the writing of data to the memory IC dies, the reading of data from the memory IC dies, and the refresh of memory IC dies.

The memory cells of a memory IC die store the bit values as a presence or absence of an electrical charge. For example, a memory cell includes a capacitive element (or elements), and a bit value is stored as a presence or absence of an electrical charge within a capacitive element. The memory cells are refreshed by reading data from the memory cells and writing the data back to the memory cells. Overtime, the capacitive elements of the memory cells leak charge, decreasing the electrical charge stored by the capacitive elements. A memory refresh process refreshes the stored data within the memory cells.

The memory refresh process is periodically performed during a memory refresh cycle. Each memory refresh cycle refreshes memory cells of a memory IC die or dies. The memory refresh process is a background process. Further, while a memory refresh process is performed, the corresponding memory cell is unavailable for read and write operations.

When a memory cell or cells are refreshed, the memory cell or cells are unavailable for read and write commands. In a memory device, the memory cells may be arranged in memory banks across different memory dies. A refresh command may be used to refresh a single memory bank or all of the memory banks. Refreshing each memory bank individually uses multiple refresh commands to refresh more than one memory banks. Using multiple refresh commands reduces how often read and/or write memory commands can be communicated, reducing the performance of the memory device. To refresh all of the memory banks, a single command may be used. However, when all of the memory banks are refreshed, all of the memory banks are inaccessible for read and/or write memory commands, reducing the performance of the corresponding memory device. The refresh process described in the following includes a refresh command that is able to refresh multiple memory banks but not all of the memory banks. Accordingly, a single refresh command may be used to refresh a portion of the memory banks, allowing other memory banks to be accessible for read and/or write commands. Thus, performance of the corresponding memory device is improved as fewer transmissions (commands) are used to refresh multiple memory banks without making all of the memory banks inaccessible. As is described in greater detail in the following, such a refresh command that is able to target multiple memory banks, but not all the memory banks, reducing the amount of time spent to refresh multiple memory banks, providing additional time to transmit memory commands, improving the performance of the corresponding memory device.

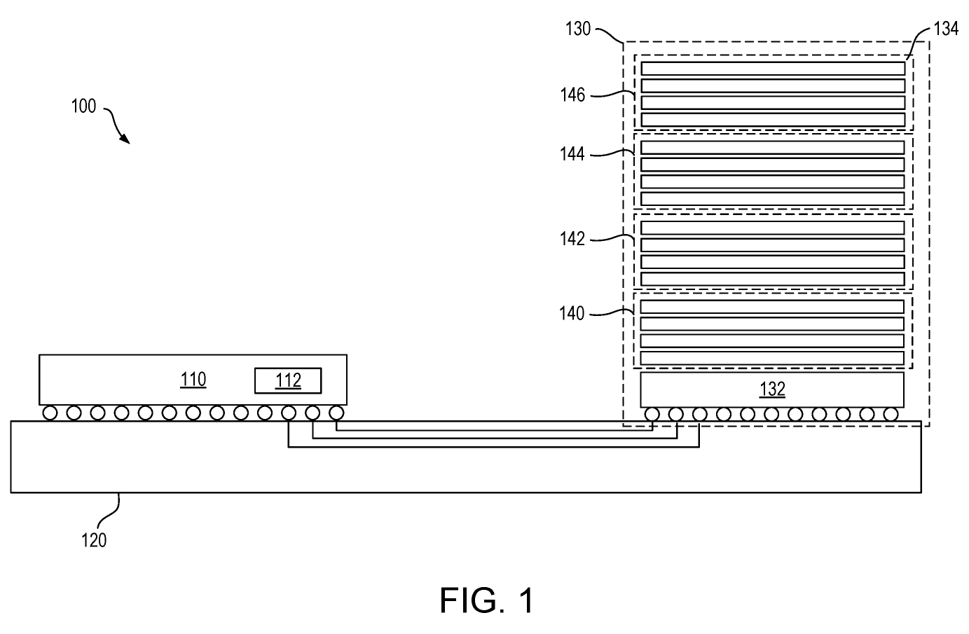

FIG. 1 illustrates an IC system 100. The IC system 100 includes an IC device 110, a substrate 120, and a memory device 130. The IC device 110 is coupled to the memory device 130 through vias and traces disposed within one or more metal layers within the substrate 120.

The IC system 100 may be referred to as a package device. In one or more examples, the IC system 100 may be referred to as a memory system. In one example, the IC system 100 is coupled to another substrate (e.g., a package substrate), and/or to other devices (e.g., processors and/or memory devices).

In one example, the IC device 110 is a processing device or devices. In one or more examples, the IC device 110 represents one or more processing devices. The one or more processing devices may be a microprocessor, a central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets, or processors implementing a combination of instruction sets. In one example, the IC device 110 may be a processing device that is one or more special-purpose processing devices such as an application specific integrated circuit (ASIC), a field programmable gate array (FPGA), a digital signal processor (DSP), network processor, or the like. The IC device 110 may be configured to execute instructions for performing the operations and steps described herein.

In one example, the IC device 110 includes memory controller circuitry 112. The memory controller circuitry 112 generates and outputs control signals for the memory device 130. For example, the memory controller circuitry 112 receives data signals and/or other signals and generates command signals (e.g., read command signals and/or write command signals) and/or control signals (e.g., refresh signals) from the data signals. The command signals and control signals are output to the memory device 130.

The substrate 120 includes one or more metal layers and dielectric layers. A metal layer is disposed between alternating dielectric layers. In one example, the substrate 120 is an interposer. In another example, the substrate 120 is a package substrate. The substrate 120 may be coupled to another substrate. In one or more examples, one or more additional processor devices and/or memory devices are disposed on and/or coupled to the substrate 120.

The memory device 130 includes a logic (or base) die 132 and memory dies 134. The memory dies 134 are interconnected with each other and the logic (or base) die 132. In one example, the memory dies 134 are vertically stacked on the logic die 132.

The logic die 132 is disposed on the substrate 120. The logic die 132 is communicatively coupled with the IC device 110. In one example, the logic die 132 receives commands from the IC device 110, and communicates the commands to the memory dies 134. In one or more examples, communicating the commands to the received commands between the memory dies 134 includes passing the commands through the logic die 132 and to the memory dies 134. In one example, the logic die 132 includes the memory controller circuitry that at least partially controls the memory dies 134 (e.g., generates read command signal, write commands signals, and/or other control signals for the memory dies 134). For example, the memory controller circuitry 112 is included within the logic die 132.

The memory dies 134 may be a volatile memory. For example, the memory dies 134 may be random access memories (RAM). In one example, the memory dies 134 are dynamic RAM (DRAM). In another example, the memory dies 134 may be other types of RAM (e.g., field-effect transistor memories, or magnetoresistive memories, among others). In one example, the memory dies are high bandwidth memories (HBM).

The memory dies 134 may be grouped into memory die groups 140, 142, 144, and 146. In other examples, the memory dies 134 may include more or less than four memory die groups. Each memory die group is identified by an identifier, or stack identifier (SID). For example, the memory die group 140 is assigned SID0, the memory die group 142 is assigned SID1, the memory die group 144 is assigned SID2, and the memory die group 146 is assigned SID3. The SID may be referred to as to the “rank” for a memory die, and is used to identify a particular memory die group when communicating with the memory dies 134.

The memory dies 134 are coupled to the IC device 110 via one or more channels. The channels are used to communicate data signals and controls signals (e.g., read command signals, write command signals, and refresh signals) from the memory controller circuitry 112 to the memory dies 134. In one example, the memory dies 134 are coupled to the IC device 110 via N channels. N is two or more. In one example, N is 16. In other examples, N is greater than or less than 16.

In one example, the one or more channels are used by each memory die of each group 140, 142, 144, and 146 of memory dies 134 to couple with the memory controller circuitry 112 of the IC device 110. For example, each memory die in each group 140, 142, 144, and 146 of the memory dies 134 is coupled to the IC device 110 via a different one or more of the channels. Each memory die within each group 140, 142, 144, and 146 is assigned an SID and one or more channels. The SID and channels are used to communicate signals from the memory controller circuitry 112 to a respective memory die. In another example, a channel may be constructed with memory banks of different memory dies within a group 140, 142, 144, and/or 146. For example, a channel may be constructed with memory banks in memory dies 140-1 and 140-2.

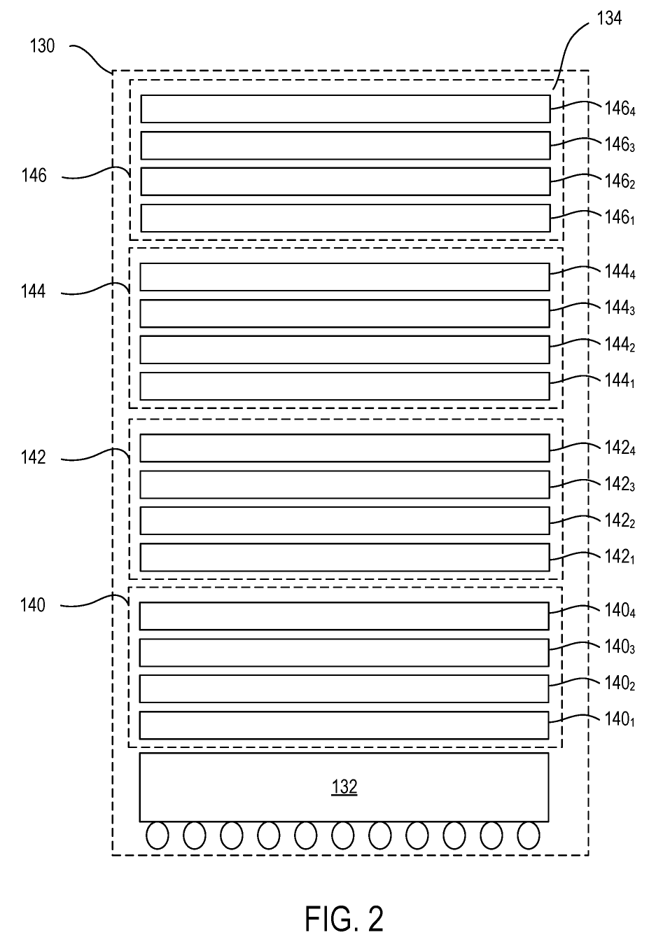

With reference to FIG. 2, the memory dies 134 of the memory device 130 include 16 memory dies 140₁-146₄, grouped into memory die groups 140-146. Each of the memory die groups 140-146 has four memory dies. In other examples, more than or less than four groups may be used, and/or, each group may have more than or less than four memory dies 140₁-146₄.

The memory die group 140 includes memory dies 140₁-140₄. The memory die group 140 is assigned SID0. Further, memory die 140₁is assigned channels 0-3, the memory die 140₂is assigned channels 4-7, the memory die 140₃is assigned channels 8-11, and the memory die 140₄is assigned channels 12-15.

The memory die group 142 includes memory dies 142₁-142₄. The memory die group 142 is assigned SID1. Further, memory die 142₁is assigned channels 0-3, the memory die 142₂is assigned channels 4-7, the memory die 142₃is assigned channels 8-11, and the memory die 142₄is assigned channels 12-15.

The memory die group 144 includes memory dies 144₁-144₄. The memory die group 144 is assigned SID2. Further, memory die 144₁is assigned channels 0-3, the memory die 144₂is assigned channels 4-7, the memory die 144₃is assigned channels 8-11, and the memory die 144₄is assigned channels 12-15.

The memory die group 146 includes memory dies 146₁-146₄. The memory die group 146 is assigned SID3. Further, memory die 146₁is assigned channels 0-3, the memory die 146₂is assigned channels 4-7, the memory die 146₃is assigned channels 8-11, and the memory die 146₄is assigned channels 12-15.

A memory die in each group 140-146 is assigned to a common channel or channels. Accordingly, to communicate with a particular memory die, an SID (or rank) and channel (or channels) are used. For example, SID0 and one or more of the channels 1-4 are used to communicate with the memory die 140₁, and SID1 and one or more of the channels 1-4 are used to communicate with the memory die 142₁.

In one or more examples, each SID (or rank) has (is associated with) one or more banks of a memory die. In one example, an SID is associated with at least two banks of a memory die. Each bank includes one or more memory cells of a memory die (e.g., memory dies 140-146). In one example, each bank includes a two dimensional matrix of memory cells comprising rows and columns. In other examples, other configurations of memory cells may be used.

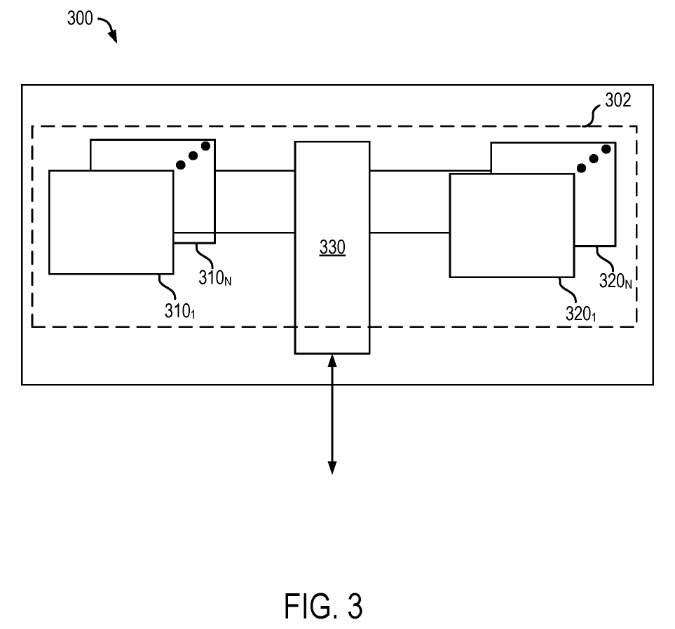

FIG. 3 illustrates a memory die 300. The memory die 300 may be representative of any of the memory dies 140-146. The memory die 300 includes memory banks 310 and 320. Each of the memory banks 310 and 320 includes (e.g., is associated with) a respective one or more memory cells of the memory die 300. In one example, the memory banks 310 include memory banks 310₁– 310_{N}, where N is two or more. The memory banks 320 include memory banks 320₁– 320_{N}, where N is two or more. While FIG. 3 illustrates that there are N memory banks in each group of memory banks 310 and 320, in other examples, one or more of the groups of memory banks includes a different number of the memory banks than another group of memory banks. For example, the number of the memory banks 310 may be greater than or less than the number of memory banks 320.

The memory banks 310 and 320 are associated with the channel 302. In one or more examples, the memory banks 310 and 320 are connected to the input/output circuitry 330. The input/output circuitry 330 communicates signals to and from the memory banks 310 and 320.

In one or more examples, as each of the memory banks 310 and 320 are included within a common memory die (e.g., the memory die 300). The memory banks 310 and 320 are associated with a common SID.

In one or more examples, the memory dies 140-146 are configured similar to the memory die 300. In one or more examples, to communicate with a particular memory die, an SID and channel (or channels) are used. In an example where the memory die 300 is associated with SID0, SID0 and the channel 302 are used to communicate with the memory banks 310 and 320. Accordingly, to refresh the memory banks 310 and 320, a refresh command is sent using SID0 and the channel 302.

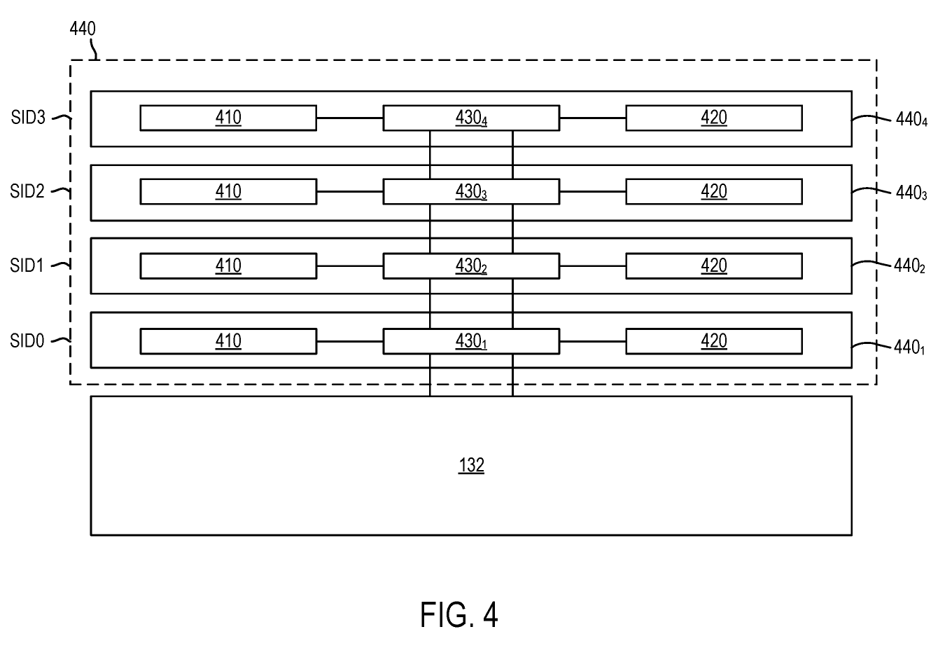

FIG. 4 illustrates a portion of the memory device 130 of FIGS. 1 and 2. FIG. 4 illustrates the memory dies 440₁– 440₄. Each of the memory dies 440₁- 440₄is configured similar to the memory die 300 of FIG. 3 and/or the memory dies 140, 142, 144, and 146 of FIG. 1. For example, the memory dies 440₁– 440₄include a memory bank 410, a memory bank 420, and input/output circuitry 430. The memory banks 410 and 420 of each memory die 440 are connected to a respective input/output circuitry 430. The memory banks 410 and 420 are configured similar to the memory banks 310 and 320 of FIG. 3. The input/output circuitry 430 is configured similar to the input/output circuitry 330 of FIG. 3. In one example, the input/output circuitry 430 is omitted, and the memory banks 410 and 420 are connected directly to the logic die 132. While FIG. 4 illustrates that each memory die 440 includes two memory banks (e.g., the memory banks 410 and 420), in one or more examples, the memory banks 410 and 420 are representative of two or more memory banks as is illustrated in the example of FIG. 3.

In one or more examples, to communicate with each of the memory banks 410 and 420 of the memory dies 440, a respective SID is used. For example, to communicate with the memory bank 410 of the memory die 440₄, the SID3 is used. In one or more examples to refresh each of the memory banks 410 and 420 of the memory dies 440, a refresh command is sent per SID. To refresh each of the memory banks 410 in each memory die 440, a refresh command is sent for each of SID0 – SID3. Accordingly, four refresh commands are sent to refresh the memory banks 410. Stated differently a refresh command is sent out per SID. Accordingly, to refresh the same memory bank each of the memory dies 440, four refresh commands are communicated, increasing the transmission time used to perform a refresh of the memory banks. As the time spent to issue refresh commands increases, there is less time to issue read memory commands and write memory commands, decreasing the performance of a memory device. In one or more examples, an all bank refresh command can be used. With reference to FIG. 4, the refresh all command refreshes all of the memory banks 410 and 420 in the memory dies 440. However, refreshing all of the memory banks 410 and 420 takes all of the memory banks 410 and 420 off line, making the memory banks 410 and 420 inaccessible. While an all bank refresh command can be used to refresh multiple memory banks, the all bank refresh command renders all of the memory banks inaccessible, halting the execution of memory commands and reducing performance of the corresponding memory device.

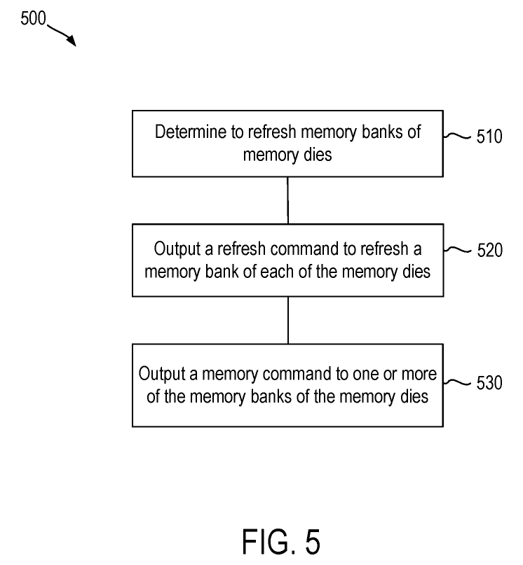

As is described in the method 500 of FIG. 5, a single refresh command may be used to refresh the same memory bank(s) in all of the corresponding memory dies or SIDs. For example with reference to FIG. 4, a single refresh command may be used to refresh the memory bank 410 in each of the memory dies 440₁– 440₄. In another example, a single refresh command may be used to refresh the memory bank 420 in each of the memory dies 440₁– 440₄.

FIG. 5 illustrates a flowchart of the method 500. The method 500 is performed by the IC system 100 of FIG. 1. In one example, the method 500 is performed by the IC device 110 of FIG. 1. For example, the method 500 is performed by the memory controller circuitry 112 of FIG. 1.

At operation 510 of the method 500, a determination to refresh memory banks of two or more memory dies is made. For example, the memory controller circuitry 112 of FIG. 1 determines to perform a refresh of the memory banks 410 or 420 of the memory dies 440. As is illustrated in FIG. 4, each of the memory dies 440 is associated with a different SID (e.g., SID0 – SID3). In one example, the memory controller circuitry 112 determines to refresh the memory banks 410 or 420 periodically. In one or more examples, the memory controller circuitry 112 determines to refresh the memory banks based on the passing of an amount of time (or period). In one or more examples, a refresh is determined to be completed based on the completion of a number of commands (e.g., after the completion of a number of commands) for a memory bank, channel, and/or memory die. In another example, a refresh is completed based on an indication that there is an opportunity to issue the refresh command. For example, the refresh may be completed when read and/or write memory commands are not being executed. In another example, the page status of a channel may be used to determine when to perform a refresh.

At operation 520 of the method 500, a refresh command is output. For example, the memory controller circuitry 112 outputs a refresh command to the memory dies 440 to refresh the memory banks 410 in each of the memory dies 440. The memory banks 410 in each of the memory dies 440 are refreshed during a first period based on the received refreshed command. In one example, the refresh command targets each of memory dies 440₁- 440₄via SID0 – SID3 to refresh the memory banks 410. The memory banks 410 are refreshed during a first period. During the first period, refreshing the memory banks 410 of each of the memory dies overlaps with each other. Further, during the first period, and while the memory banks 410 are refreshed, the memory banks 410 of the memory dies are inaccessible by the memory controller circuitry 112. For example, data cannot be written to the memory banks 410 or read from the memory banks 410 during the first period and while the memory banks 410 are refreshed. Stated another way, when the memory banks 410 are refreshed, memory commands associated with the memory banks 410 are not able to be executed.

The memory banks 420 are accessible during the first period, and while the memory banks 410 are refreshed. Further, the memory banks of other memory dies (e.g., the memory dies 140, 142, 144, and 146) are accessible during the first period and while the memory banks 410 are refreshed. A memory bank that is accessible is a memory bank that can be written to or read from. In one more examples, a memory bank that is accessible is a memory bank for which a memory command can be executed (e.g., a read memory command or write memory command). In one example during the first period, data is read from or data is written to one or more of the memory banks 420 of the memory dies 440₁– 440₄or another memory bank of another memory die. For example during the first period (e.g., a period during which the memory banks 410 are refreshed), the memory controller circuitry 112 outputs a read memory command or a write memory command) to one or more of the memory banks 420 of the memory dies 440₁– 440₄.

In one example, the refresh command includes an indication (or flag) that indicates which memory banks are to be refreshed. The indication may be a high voltage level (e.g., a logic value of 1) or low voltage level (e.g., a logic value of 0). Further, the refresh command may include an indication as which SIDs are to be refreshed. To refresh each of the memory banks for the SIDs, the refresh command may indicate that each of SIDs are to be refreshed. For example, to refresh the memory banks 410 of the memory dies 440, the refresh command indicates that each of SID0 – SID3 are to be refreshed. The indication may be a voltage value (or a corresponding logic value).

In one example, the memory banks 420 of the memory dies 440₁- 440₄are refreshed as described above with regard to the memory banks 410 during a second period. The second period occurs after the first period.

In one or more examples based on receiving the refresh command, the memory dies 440₁– 440₄perform a refresh of the memory banks 410. For example, the memory device 130 receives the refresh command and determines that the refresh command is associated with each SID0 – SID4, and the memory banks 410. In one example, a combination of the indicated SIDs of the refresh command, the indicated memory banks of the refresh command, and the channel used to community the refreshed command is used to determine which memory banks to refresh. The input/output circuitry 430 (or, in some examples, the logic die 132) identifies which memory banks of which memory die or dies are to be refreshed based on the voltage values (e.g., indications or flags) of the refresh command. In one example, input/output circuitry 430 (or, in some examples, the logic die 132) determines that the memory banks 410 of the memory dies 440₁– 440₄are to be refreshed based on the refresh command including an indication to refresh the memory banks 410, and an indication that the refresh command is intended for SID0 – SID3, and that the refresh command is associated (e.g., sent or communicated) with an associated channel. Accordingly, the refresh command is provided to the memory banks 410 of the memory dies 440 to refresh the memory banks.

At 530, a memory command is output to one or more of the memory banks of the memory dies. The memory command is output (issued) to one of the memory banks that was refreshed during the first period. The memory command is a write memory command or a read memory command. In one example, the memory controller circuitry 112 outputs the memory command to the memory device 130 to write data to or read data from one of the memory banks 410 of the memory dies 440₁– 440₄. The memory command is output during a second period that is subsequent to (e.g., follows) the first period. The memory device 130 receives the memory command and the memory command is performed (executed) by the corresponding memory die or dies 140. In one example, the input/output circuitry 430 (or, in some examples, the logic die 132) identifies which of the memory dies 440 to output the memory command from the memory command and outputs the memory command to the identified memory die. The memory die receives and performs the memory command.

In one example, the memory system 100 is configured to use one or more refresh processes. For example, the memory system 100 may use the refresh process to refresh a memory bank of multiple memory dies as is described with regard to the method 500 of FIG. 5. In one or more examples, the memory system 100 may additionally use a per memory bank and per SID refresh process, an all bank all SID refresh process, and/or other refresh processes.

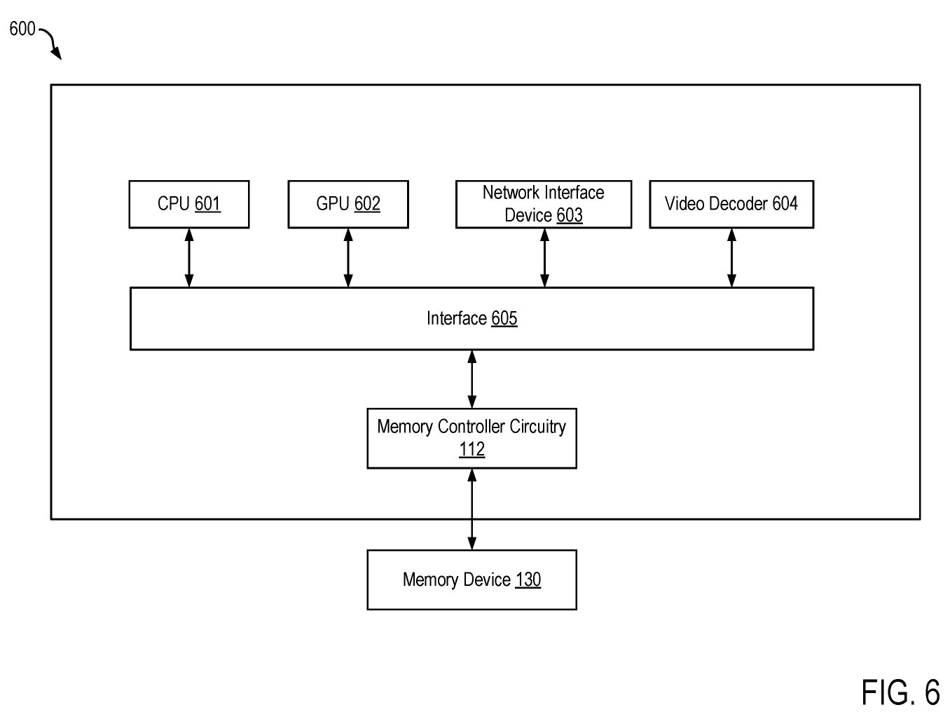

FIG. 6 illustrates a computer system 600. The computer system 600 includes one or more chips. The computer system 600 includes a central processing unit (CPU) 601, graphics processing unit (GPU) 602, network interface device 603, video decoder 604, interface 605, the memory controller circuitry 112, and the memory device 130. The CPU 601 and/or the GPU 602 may correspond to the IC device 110 of FIG. 1. In one or more examples, the computer system 600 is just one example of a computer system. In other examples, the computer system 600 may include fewer components than what is shown in FIG. 6. For example, the computer system 600 may not include the GPU 602, the network interface device 603, and/or the video decoder 604. In one or more examples, the computer system 600 may include additional devices than the ones shown in FIG. 6. Thus, FIG. 6 is just one example of components that can be included in a computer system 600.

The CPU 601 can represent any number of processors where each processor can include any number of cores. For example, the CPU 601 can include processors arranged in array, or the CPU 601 can include an array of cores. In one embodiment, the CPU 601 is an x86 processor that uses a corresponding complex instruction set. However, in other embodiments, the CPU 601 may be other types of CPUs such as an Advanced Reduced Set Instruction Computer (RSIC) Machine (ARM) processor.

The GPU 602 is an internal GPU 602 that performs accelerated computer graphics and image processing. The GPU 602 can include any number of different processing elements. In one embodiment, the GPU 602 can perform non-graphical tasks such as training an AI model or cryptocurrency mining.

The network interface device 603 allows for the computer system 600 to communicate over a network. The network may be a wired and/or wireless network.

The video decoder 604 can be used for decoding and encoding videos.

The memory controller circuitry 112 controls the memory device 130. The memory device 130 is described in greater detail in the following. The memory device 130 may be included within a common chip with the CPU 601, the GPU 602, the network interface device 603, the video decoder 604, the interface 605, and/or the memory controller circuitry 112. In one or more examples, two or more of the CPU 601, the GPU 602, the network interface device 603, the video decoder 604, the interface 605, and the memory controller circuitry 112 are included in a common chip.

The CPU 601, the GPU 602, the network interface device 603, the video decoder 604, and the memory controller circuitry 112 are communicatively coupled using an interface 605. Put differently, the interface 605 permits the different types of circuitry in the computer system 600 to communicate with each other. For example, the CPU 601 can use the interface 605 to communicate with the memory controller circuitry 112 and the memory device 130.

In one example, the computer system 600 is part of a distributed computer system. In such an example, the computer system 600 is a server computer system. In such an example, the distributed computer system includes multiple computer systems that are configured similar to the computer system 600. In one or more examples, each of the computer systems are connected via a network (wireless or wired connections), and each of the computer systems include network interconnect circuitry that is used communicate with each other.

The refresh process as described above uses a single refresh command to refresh the same memory bank across multiple SIDs, but not all memory banks within the memory device. Thus, performance of the corresponding memory device and memory system is improved as fewer transmissions (commands) are used to refresh multiple memory banks without making all of the memory banks inaccessible.

While the foregoing is directed to specific examples, other and further examples may be devised without departing from the basic scope thereof, and the scope thereof is determined by the claims that follow.

What is claimed is:

1. A memory system comprising:
one or more memory dies having a first memory bank, a second memory bank, a third memory bank, and a fourth memory bank, wherein the first memory bank is associated with a first identifier and the third memory bank is associated with a second identifier; and
memory controller circuitry coupled to the one or more memory dies, wherein the memory controller circuitry is configured to output a refresh command to the one or more memory dies to refresh the first memory bank and the third memory bank during a first period, and wherein the second memory bank and the fourth memory bank are accessible by the memory controller circuitry during the first period.

2. The memory system of claim 1, wherein the first memory bank and the second memory bank are within a first memory die of the one or more memory dies, and the third memory bank and the fourth memory bank are within a second memory die of the one or more memory dies.

3. The memory system of claim 2, wherein the first memory die is associated with a first stack identifier and the second memory die is associated with a second stack identifier.

4. The memory system of claim 1, wherein at least one of the second memory bank and the fourth memory bank are configured to execute a memory command during the first period.

5. The memory system of claim 1, wherein the memory controller circuitry is further configured to output a memory command to one of the first memory bank and the second memory bank during a second period subsequent to the first period.

6. The memory system of claim 1, wherein the one or more memory dies are part of a high bandwidth memory device.

7. The memory system of claim 1, wherein a first memory die of the one or more memory dies is vertically stacked on a second memory die of the one or more memory dies.

8. A memory controller of a memory system configured to:
output a refresh command to one or more memory dies of the memory system to refresh a first memory bank of the one or more memory dies and a third memory bank of the one or more memory dies during a first period, and wherein a second memory bank of the one or more memory dies and a fourth memory bank of the one or more memory dies are accessible by the memory controller during the first period.

9. The memory controller of claim 8, wherein the first memory bank and the second memory bank are within a first memory die of the one or more memory dies, and the third memory bank and the fourth memory bank are within a second memory die of the one or more memory dies.

10. The memory controller of claim 9, wherein the first memory die is associated with a first stack identifier and the second memory die is associated with a second stack identifier.

11. The memory controller of claim 8 further configured to output a memory command to at least one of the second memory bank and the fourth memory bank during the first period.

12. The memory controller of claim 8 further configured to output a memory command to one of the first memory bank and the second memory bank during a second period subsequent to the first period.

13. The memory controller of claim 8, wherein the one or more memory dies are part of a high bandwidth memory device.

14. The memory controller of claim 8, wherein a first memory die of the one or more memory dies is vertically stacked on a second memory die of the one or more memory dies.

15. A method comprising:
outputting, from memory controller circuitry to one or more memory dies, a refresh command; and
refreshing, a first memory bank of the one or more memory dies and a third memory bank of the one or more memory dies during a first period based on the refresh command, wherein a second memory bank of the one or more memory dies and a fourth memory bank of the one or more memory dies are accessible by the memory controller circuitry during the first period.

16. The method of claim 15, wherein the first memory bank and the second memory bank are within a first memory die of the one or more memory dies, and the third memory bank and the fourth memory bank are within a second memory die of the one or more memory dies.

17. The method of claim 16, wherein the first memory die is associated with a first stack identifier and the second memory die is associated with a second stack identifier.

18. The method of claim 15 further comprising outputting, from the memory controller circuitry, a memory command to one of the first memory bank and the second memory bank during a second period subsequent to the first period.

19. The method of claim 15 further comprising outputting a memory command to one of the first memory bank and the second memory bank during a second period subsequent to the first period.

20. The method of claim 15, wherein the one or more memory dies are part of a high bandwidth memory device.
